(19) United States
(12) Patent Application Publication
(10) Pub. No.: US 2026/0114144 A1
(43) Pub. Date: Apr. 23, 2026

(54) DISPLAY PANEL AND ELECTRONIC DEVICE

(71) Applicant: POSTECH RESEARCH AND BUSINESS DEVELOPMENT FOUNDATION, Pohang-si (KR)

(72) Inventors: Changsoon CHO, Pohang-si (KR); Wanhee LEE, Pohang-si (KR)

(21) Appl. No.: 19/366,531

(22) Filed: Oct. 23, 2025

(30) Foreign Application Priority Data
Oct. 23, 2024 (KR) 10-2024-0146121
Oct. 22, 2025 (KR) 10-2025-0153405

(51) Int. Cl. H10K 59/35

(52) U.S. Cl. CPC H10K 59/353

(57) ABSTRACT

Embodiments provide a display panel and an electronic device. The display panel includes a non-radiative element and a light-emitting layer configured to emit light of a first wavelength spectrum from non-radiative energy transferred from the non-radiative element.

### CROSS-REFERENCE TO RELATED APPLICATION

This application claims priorities to Korean Patent Applications No. 10-2024-0146121 filed on Oct. 23, 2024 and No. 10-2025-0153405 filed on Oct. 22, 2025, and all the benefits accruing therefrom under 35 U.S.C. § 119, the content of which in its entirety is herein incorporated by reference.

### BACKGROUND

### 1. Field

Display panels and electronic devices are disclosed.

### 2. Description of the Related Art

An electronic device including a display panel such as a liquid crystal display panel or a light emitting diode display panel is commercialized. In recent years, a research has been conducted to improve color characteristics by using a liquid crystal display panel or a light emitting diode display panel as a light source and employing a photoluminescent layer configured to convert light of a predetermined wavelength spectrum supplied from the light source into light of another wavelength spectrum.

### SUMMARY OF THE INVENTION

However, in order for light supplied from the light source to be sufficiently absorbed by the photoluminescent layer, the photoluminescent layer with a thickness of several to several hundred micrometers may be required and such a thick photoluminescent layer may not only deteriorate the luminescence efficiency and spatial resolution of the display panel but also limit the patterning precision, resulting in limitations when applied to small-sized displays. In addition, since it may be difficult for the light supplied from the light source to be completely absorbed in the photoluminescent layer, the light emitted from the photoluminescent layer may inevitably include the light supplied from the light source, resulting in a degradation of color characteristics, or a separate optical filter for solving this issue may be required.

An embodiment provides a display panel capable of overcoming thickness and process limitations and improving display quality including color characteristics.

Another embodiment provides an electronic device including the display panel.

According to an embodiment, a display panel includes a non-radiative element, and a light-emitting layer configured to emit light of a first wavelength spectrum from non-radiative energy transferred from the non-radiative element.

The non-radiative element may be a non-radiative diode including a first opaque electrode positioned adjacent to the light-emitting layer.

The non-radiative diode may further include a second opaque electrode opposing the first opaque electrode, and a dipole generating layer between the first opaque electrode and the second opaque electrode.

A ratio of a vertically aligned dipoles among dipoles in the dipole generating layer may be greater than about 50%.

The dipole generating layer may include an electroluminescent material configured to emit light of a second wavelength spectrum that is shorter than the first wavelength spectrum, the electroluminescent material may be configured to convert electrical energy into radiative energy and the non-radiative energy, and the radiative energy may be confined or trapped in the dipole generating layer.

The non-radiative energy may be converted into a surface plasmon polariton mode at a surface of the first opaque electrode and transferred to the light-emitting layer.

The first wavelength spectrum may be a green wavelength spectrum or a red wavelength spectrum, and the second wavelength spectrum may be a blue wavelength spectrum.

The external quantum efficiency of the non-radiative diode may be less than about 1%.

The first opaque electrode may include a metal layer having a light-transmittance of less than about 30% for light of the second wavelength spectrum.

A distance between the light-emitting layer and the first opaque electrode may be less than about 25 nm.

A thickness of the light-emitting layer may be greater than or equal to about 2 nm and less than about 1 μm.

The light-emitting layer may include quantum dots, perovskites, phosphors, organic light-emitting materials, or a combination thereof.

According to another embodiment, a display panel includes a first sub-pixel displaying red, a second sub-pixel displaying green, and a third sub-pixel displaying blue, wherein the first sub-pixel includes a first non-radiative element and a red light-emitting layer configured to emit light of a red wavelength spectrum from non-radiative energy transferred from the first non-radiative element, and the second sub-pixel may include a second non-radiative element and a green light-emitting layer configured to emit light of a green wavelength spectrum from non-radiative energy transferred from the second non-radiative element.

The first non-radiative element and the second non-radiative element may each include a first opaque electrode positioned adjacent to the red light-emitting layer or the green light-emitting layer, a second opaque electrode opposing the first opaque electrode, and a dipole generating layer positioned between the first opaque electrode and the second opaque electrode, wherein the dipole generating layer may include an electroluminescent material configured to emit energy corresponding to a blue wavelength spectrum.

The electroluminescent material may be configured to convert electrical energy into radiative energy and non-radiative energy, the radiative energy may be confined or trapped in the dipole generating layer, and the non-radiative energy may be converted into a surface plasmon polariton mode at a surface of the first opaque electrode and transferred to the red light-emitting layer and the green light-emitting layer, respectively.

A ratio of the vertically aligned dipoles among dipoles in the dipole generating layer may be greater than about 50%.

The first opaque electrode may include a metal layer having a light-transmittance of less than about 30% for light in the blue wavelength spectrum, and a thickness of each of the red light-emitting layer and the green light-emitting layer may be greater than or equal to about 2 nm and less than about 1 μm.

The third sub-pixel may include a radiative element including an electroluminescent material configured to emit light of a blue wavelength spectrum.

The display panel may not include a color filter.

According to another embodiment, an electronic device includes the display panel.

The limitations of thickness and process may be overcome and display quality including color characteristics may be improved.

### BRIEF DESCRIPTION OF THE DRAWINGS

FIG. 1 is a plan view showing an example of an arrangement of sub-pixels of the display panel according to an embodiment,

FIG. 2 is a cross-sectional view taken along line II-II of the display panel of FIG. 1,

FIG. 3 is a graph showing the emission spectrum (T) of the device according to Example 2, the emission spectrum of the perovskite light-emitting layer, and the emission spectrum of the non-radiative element,

FIG. 4 is a graph showing the emission spectrum of the device according to Example 3, the emission spectrum of the perovskite light-emitting layer, and the emission spectrum of the non-radiative element,

FIG. 5 is a graph showing the emission spectrum of the device according to Reference Example 5, the emission spectrum of the perovskite light-emitting layer, and the emission spectrum of the non-radiative element, and

FIG. 6 is a graph showing the emission spectrum of the device according to Reference Example 6, the emission spectrum of the perovskite light-emitting layer, and the emission spectrum of the non-radiative element.

### DETAILED DESCRIPTION OF THE EMBODIMENTS

Hereinafter, the embodiments will be described in detail so that those of ordinary skill in the art may easily implement them. However, the actually applied structure may be implemented in several different forms and is not limited to the embodiments described herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “about” may mean within ±10%, ±5%, ±3%, or ±1% of the indicated value or within a standard deviation.

An example of a display panel according to an embodiment is described with reference to the drawings.

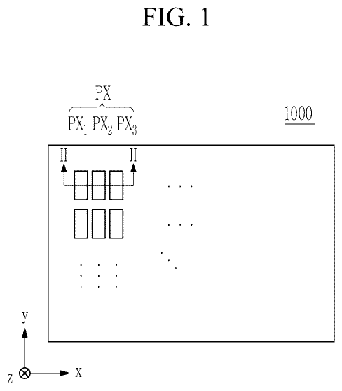

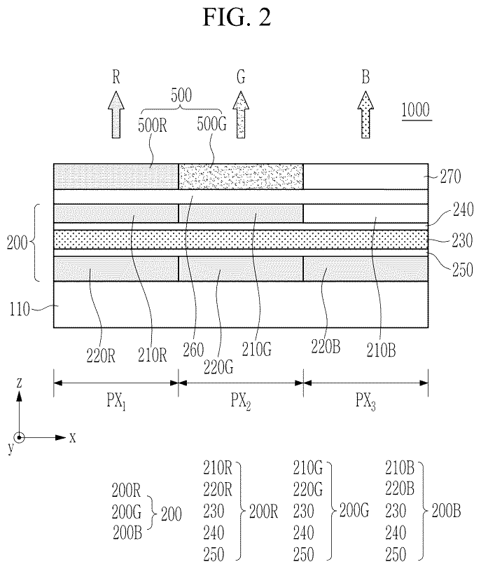

FIG. 1 is a plan view showing an example of an arrangement of sub-pixels of a display panel according to an embodiment, and FIG. 2 is a cross-sectional view taken along line II-II of the display panel of FIG. 1.

Referring to FIG. 1, the display panel 1000 according to an embodiment includes a plurality of pixels PX arranged along rows (for example, the x direction) and/or columns (for example, the y direction), and each pixel PX includes a plurality of sub-pixels PX₁, PX₂, PX₃ displaying different colors from each other. Herein, as one example, a configuration in which three sub-pixels PX₁, PX₂ and PX₃ form a single pixel is illustrated, but the disclosure is not limited thereto and may further include an additional sub-pixel such as a white sub-pixel and/or may further include one or more sub-pixels displaying the same color. A plurality of pixels PX may be arranged, for example, in a Bayer matrix, PenTile matrix, and/or diamond matrix, but is not limited thereto.

Each sub-pixel PX₁, PX₂, PX₃ may display a color among three primary colors or a combination of three primary colors, and for example, may display a color of red, green, blue, or a combination thereof. As an example, the first sub-pixel PX₁ may display red, the second sub-pixel PX₂ may display green, the third sub-pixel PX₃ may display blue, and each pixel PX may display full color.

In the drawings, although all sub-pixels PX₁, PX₂, PX₃ are shown as having the same size, the present disclosure is not limited thereto, and at least one of the sub-pixels PX₁, PX₂, PX₃ may be larger or smaller than the other sub-pixels PX₁, PX₂, PX₃. In the drawings, although all sub-pixels PX₁, PX₂, PX₃ are shown as having the same shape, the present disclosure is not limited thereto, and at least one of the sub-pixels PX₁, PX₂, PX₃ may have a different shape from the other sub-pixels PX₁, PX₂, PX₃.

Referring to FIG. 2, a display panel 1000 according to an embodiment includes a substrate 110, an energy supply element 200, and a light-emitting layer 500.

The substrate 110 may be a backplane substrate including a supporting substrate and a switching/driving element positioned on the supporting substrate, and the switching/driving element may include, for example, a thin film transistor (TFT) (not shown). The TFT may be included in one or two or more for each sub-pixel PX₁, PX₂, PX₃, and may independently control and/or drive the energy supply element 200 included in each sub-pixel PX₁, PX₂, PX₃.

The energy supply element 200 may be a non-radiative element (non-light emitting element) that supplies non-radiative energy (non-light emitting energy) to the light-emitting layer 500 to be described later, or may be a radiative element (a light-emitting element) that emits radiative energy (luminescent energy) according to the sub-pixels PX₁, PX₂, PX₃. Some of the energy supply elements 200 of the sub-pixels PX₁, PX₂, PX₃ may be non-radiative elements, and some of the energy supply elements 200 of the sub-pixels PX₁, PX₂, PX₃ may be radiative elements.

The light-emitting layer 500 may be configured to emit light of a predetermined wavelength spectrum by being supplied non-radiative energy from the energy supply element 200, which is a non-radiative element. The non-radiative element may be, for example, a non-radiative diode (a non-light emitting diode), and the radiative element may be, for example, a radiative diode (a light-emitting diode).

A non-radiative diode may be configured to transfer non-radiative energy (for example, energy of a surface plasmon polariton (SPP) mode to be described later) in a form other than radiative energy (luminescent energy) that emits light, and may be referred to as a light-transferring diode (LTD) instead of a light emitting diode. Since the non-radiative diode does not substantially emit light externally, it may exhibit a very low external quantum efficiency, and for example, may be less than about 1%.

The non-radiative diode and the radiative diode may each generate dipoles by electrical stimulation, and the generated dipoles may be converted into radiative energy and non-radiative energy. While the radiative diode may mainly transfer energy to the outside of the radiative diode in the form of the radiative energy, the non-radiative diode may confine or trap most of the radiative energy inside the non-radiative diode to minimize transfer of the radiative energy to the outside, while primarily transferring energy outside (e.g., toward the light-emitting layer 500) in the form of non-radiative energy.

Specifically, when the first, second, and third sub-pixels PX₁, PX₂ and PX₃ respectively display red, green, and blue, respectively, the energy supply element 200 may supply energy corresponding to the blue wavelength spectrum, which has the highest energy among the red wavelength spectrum, green wavelength spectrum, and blue wavelength spectrum, to the light-emitting layers 500R and 500G of the first and second sub-pixels PX₁ and PX₂ in the form of non-radiative energy, and may supply energy to the third sub-pixel PX₃ in the form of radiative energy.

The red light-emitting layer 500R of the first sub-pixel PX₁ may be transferred non-radiative energy from the energy supply element 200 and emit light of a red wavelength spectrum, and the green light-emitting layer 500G of the second sub-pixel PX₂ may be transferred non-radiative energy from the energy supply element 200 and emit light of a green wavelength spectrum. The third sub-pixel PX₃ may display blue by the radiative energy of the blue wavelength spectrum supplied from the energy supply element 200 without a separate light-emitting layer, as it displays the same color as the blue wavelength spectrum supplied from the energy supply element 200.

For example, the first sub-pixel PX₁ displaying red may include a non-radiative element 200R as the energy supply element 200, and a red light-emitting layer 500R that receives non-radiative energy transferred from the non-radiative element 200R and emits light in the red wavelength spectrum.

For example, the second sub-pixel PX₂ displaying green may include a non-radiative element 200G as the energy supply element 200, and a green light-emitting layer 500G that receives non-radiative energy transferred from the non-radiative element 200G and emits light in a green wavelength spectrum.

The non-radiative element 200R of the first sub-pixel PX₁ and the non-radiative element 200G of the second sub-pixel PX₂ may each be a non-radiative diode, and may each include an upper electrode 210R and 210G and a lower electrode 220R and 220G facing each other; a dipole generating layer 230 positioned between the upper electrode 210R and 210G and the lower electrode 220R and 220G; and auxiliary layers 240 and 250 positioned between the upper electrode 210R and 210G and the dipole generating layer 230 and between the lower electrode 220R and 220G and the dipole generating layer 230, respectively.

One of the upper electrodes 210R and 210G and the lower electrodes 220R and 220G may be an anode, and the other may be a cathode. The lower electrodes 220R and 220G may be a pixel electrode independently separated for each sub-pixel PX₁ and PX₂, and the upper electrodes 210R and 210G may be a common electrode to which a common voltage is applied. The upper electrodes 210R and 210G may be positioned adjacent to the light-emitting layer 500 and, for example, may face the light-emitting layer 500 with an optical spacer 260, which will be described later, interposed therebetween.

The upper electrodes 210R and 210G and the lower electrodes 220R and 220G may each be an opaque electrode, and a pair of opaque electrodes facing each other may block dipoles generated from the dipole generating layer 230, which will be described later, and the radiative energy (photon) generated therefrom from escaping to the outside of the non-radiative element 200R of the first sub-pixel PX₁ and the non-radiative element 200G of the second sub-pixel PX₂, and may confine or trap the dipoles and the radiative energy inside the non-radiative element 200R of the first sub-pixel PX₁ and the non-radiative element 200G of the second sub-pixel PX₂.

The opaque electrode may include a metal layer and/or a metal alloy layer (hereinafter, referred to as ‘metal layer’) that may substantially not transfer radiative energy (for example, light of a blue wavelength spectrum) generated from the dipole generating layer 230. The metal layer may have a thickness of, for example, a transmittance of light in a blue wavelength spectrum (for example, greater than or equal to about 450 nm and less than about 500 nm, for example, based on a wavelength of about 475 nm) of less than about 30%, and within the above range, the transmittance of light in a blue wavelength spectrum may be greater than or equal to 0 and less than about 30%, 0 to about 25%, 0 to about 20%, 0 to about 18%, 0 to about 15%, 0 to about 10%, 0 to about 8%, 0 to about 5%, 0 to about 2%, greater than or equal to about 1 and less than about 30%, about 1 to about 25%, about 1 to about 20%, about 1 to about 18%, about 1 to about 15%, about 1 to about 10%, about 1 to about 8%, about 1 to about 5%, or about 1 to about 2%.

The metal layer may have a thickness of, for example, about 10 nm or greater, and within the above range, may be about 12 nm or greater, about 15 nm or greater, about 20 nm or greater, about 25 nm or greater, about 30 nm or greater, about 40 nm or greater, about 50 nm or greater, about 60 nm or greater, about 70 nm or greater, or about 80 nm or greater, and may have a thickness of about 10 nm to about 800 nm, about 10 nm to about 600 nm, about 10 nm to about 500 nm, about 10 nm to about 300 nm, about 10 nm to about 200 nm, about 10 nm to about 100 nm, about 12 nm to about 800 nm, about 12 nm to about 600 nm, about 12 nm to about 500 nm, about 12 nm to about 300 nm, about 12 nm to about 200 nm, about 12 nm to about 100 nm, about 15 nm to about 800 nm, about 15 nm to about 600 nm, about 15 nm to about 500 nm, about 15 nm to about 300 nm, about 15 nm to about 200 nm, about 15 nm to about 100 nm, about 20 nm to about 800 nm, about 20 nm to about 600 nm, about 20 nm to about 500 nm, about 20 nm to about 300 nm, about 20 nm to about 200 nm, about 20 nm to about 100 nm, about 25 nm to about 800 nm, about 25 nm to about 600 nm, about 25 nm to about 500 nm, about 25 nm to about 300 nm, about 25 nm to about 200 nm, about 25 nm to about 100 nm, about 30 nm to about 800 nm, about 30 nm to about 600 nm, about 30 nm to about 500 nm, about 30 nm to about 300 nm, about 30 nm to about 200 nm, about 30 nm to about 100 nm, about 40 nm to about 800 nm, about 40 nm to about 600 nm, about 40 nm to about 500 nm, about 40 nm to about 300 nm, about 40 nm to about 200 nm, about 40 nm to about 100 nm, about 50 nm to about 800 nm, about 50 nm to about 600 nm, about 50 nm to about 500 nm, about 50 nm to about 300 nm, about 50 nm to about 200 nm, about 50 nm to about 100 nm, about 60 nm to about 800 nm, about 60 nm to about 600 nm, about 60 nm to about 500 nm, about 60 nm to about 300 nm, about 60 nm to about 200 nm, about 60 nm to about 100 nm, about 70 nm to about 800 nm, about 70 nm to about 600 nm, about 70 nm to about 500 nm, about 70 nm to about 300 nm, about 70 nm to about 200 nm, about 70 nm to about 100 nm, about 80 nm to about 800 nm, about 80 nm to about 600 nm, about 80 nm to about 500 nm, about 80 nm to about 300 nm, about 80 nm to about 200 nm, or about 80 nm to about 100 nm.

The metal layer may include, for example, silver (Ag), copper (Cu), aluminum (Al), gold (Au), titanium (Ti), chromium (Cr), nickel (Ni), magnesium (Mg), calcium (Ca), an alloy thereof (for example, magnesium-silver (Mg—Ag), nitrides such as TiN), or combinations thereof, but is not limited thereto.

For example, the thickness of the metal layer satisfying a light transmittance of about less than about 30% for a predetermined wavelength spectrum may vary depending on the type of metal. For example, the metal layer may include Ag or a Ag alloy, and a thickness at which the transmittance of light in the blue wavelength spectrum (for example, about 450 nm to less than 500 nm, for example, based on a wavelength of about 475 nm) of Ag or the Ag alloy is less than about 30% may be greater than or equal to about 35 nm. For example, the metal layer may include Al or Al alloy, and a thickness at which the transmittance of light in the blue wavelength spectrum (for example, about 450 nm or more and less than 500 nm, for example, based on a wavelength of about 475 nm) of the Al or Al alloy is less than about 30% may be greater than or equal to about 10 nm.

The opaque electrode may further include a light-transmitting layer positioned on and/or under the metal layer. The light-transmitting layer may include a conductive oxide such as indium tin oxide (ITO), indium zinc oxide (IZO), zinc oxide (ZnO), tin oxide (SnO), aluminum tin oxide (AlTO), and fluorine-doped tin oxide (FTO).

For example, the upper electrode 210R of the first sub-pixel PX₁ and the upper electrode 210G of the second sub-pixel PX₂ may each be independent, and for example, the material included in the upper electrode 210R of the first sub-pixel PX₁ and the material included in the upper electrode 210G of the second sub-pixel PX₂ may be the same as or different from each other, and for example, the thickness of the upper electrode 210R of the first sub-pixel PX₁ may be the same as or different from the thickness of the upper electrode 210G of the second sub-pixel PX₂.

For example, the lower electrode 220R of the first sub-pixel PX₁ and the lower electrode 220G of the second sub-pixel PX₂ may each be independent, and, for example, the material included in the lower electrode 220R of the first sub-pixel PX₁ and the material included in the lower electrode 210G of the second sub-pixel PX₂ may be the same as or different from each other, and, for example, the thickness of the lower electrode 220R of the first sub-pixel PX₁ may be the same as or different from the thickness of the lower electrode 220G of the second sub-pixel PX₂.

The dipole generating layer 230 is positioned between the upper electrode 210R, 210G and the lower electrode 220R, 220G, and may generate dipoles by an electrical stimulus, for example, electrical energy applied to the upper electrode 210R, 210G and the lower electrode 220R, 220G. The dipole generating layer 230 may include an electroluminescent material configured to generate such dipoles, and, for example, may include an electroluminescent material configured to emit energy corresponding to a blue wavelength spectrum. The electroluminescent material may be an organic material, an inorganic material, an organic-inorganic material, or a combination thereof.

The electroluminescent material may be configured to convert electrical energy into radiative energy (photons) and non-radiative energy. The radiative energy (photons) may be repeatedly reflected between the upper electrode 210R, 210G and the lower electrode 220R, 220G, which are opaque electrodes, and may be confined or trapped in the dipole generating layer 230 and may not be substantially transferred to the light-emitting layer 500. The non-radiative energy may be converted into a surface plasmon polariton (SPP) mode formed at the surface of the upper electrode 210R, 210G and transferred to the light-emitting layer 500.

The transfer of non-radiative energy of SPP mode (hereinafter, referred to as a “non-radiative transfer of SPP mode”) may be achieved by a non-radiative electromagnetic wave transferred in a direction parallel to the surface of the metal layer of the upper electrode 210R, 210G, for example, the xy direction, and may be transferred to the light-emitting layer 500 in the form of non-radiative energy.

In a typical electroluminescent device (for example, an organic electroluminescent device, OLED), a SPP mode may correspond to light loss and may act as a cause of lowering luminous efficiency. However, in the display panel 1000 according to the present embodiment, the non-radiative energy of the SPP mode, without direct light emission from the energy supply element 200, may be absorbed in the light-emitting layer 500 to generate light of a red wavelength spectrum or green wavelength spectrum, thereby allowing energy to be effectively recycled.

For example, in the case of a display panel in which photoluminescence occurs by wavelength conversion in a light-emitting layer (a photoluminescent layer) through direct light emission from a typical electroluminescent device (for example, an organic electroluminescent device), the light-emitting layer with a thickness of several to several hundred micrometers may be required to sufficiently absorb light transferred from the electroluminescent device. Such a thick light-emitting layer may not only decrease the luminous efficiency and resolution of the display panel, but may also limit the precision of pixel patterning, making it difficult to apply to small-sized displays. For example, a light-emitting layer with a thickness of several to several hundred micrometers may experience a rapid decrease in external quantum efficiency (EQE) since the re-absorption and re-emission processes of photons in the light-emitting layer occur repeatedly.

In contrast, in the case of using non-radiative transfer of the SPP mode transferred from the non-radiative element 200R, 200G without direct light emission as described above, a thick thickness of the light-emitting layer 500 for sufficient light absorption may be not required, and the light-emitting layer 500 may have a relatively thin thickness of a nanometer level, for example, greater than or equal to several nanometers and less than about 1 μm. Moreover, since the emission in the light-emitting layer 500 may directly occur without the re-absorption and re-emission processes of photons in the light-emitting layer 500, the light-emitting layer 500 with a relatively thin thickness may be relatively free from the limitation of luminous efficiency.

Non-radiative energy of the SPP mode generated in the dipole generating layer 230 may be greater than about 50% with respect to the total sum of radiative energy and non-radiative energy, and, within the above range, may be greater than or equal to about 55%, greater than or equal to about 60%, greater than or equal to about 65%, greater than or equal to about 70%, or greater than or equal to about 75%.

To increase the non-radiative energy of the SPP mode among the radiative energy and the non-radiative energy converted from electrical energy, it may be necessary to increase vertically aligned dipoles (vertical alignment of dipoles). For example, the proportion of vertically aligned dipoles among the total of dipoles generated in the dipole generating layer 230, that is, the total of isotropic dipoles, horizontally aligned dipoles, and vertically aligned dipoles, may be greater than about 50%, and within the above range, may be greater than or equal to about 55%, greater than or equal to about 60%, greater than or equal to about 65%, greater than or equal to about 70%, or greater than or equal to about 75%. The ratio of such vertically aligned dipoles may be implemented through the type and orientation of the electroluminescent material included in the dipole generating layer 230 and/or the control of the optical resonance mode of the non-radiative element 200R, 200G.

The ratio of vertically aligned dipoles may, for example, be predicted by calculating the Purcell factor (Fₚ), which is the relative decay rate of vertically aligned dipoles, and the Purcell factor may be calculated by the following Relational Equation 1.

$${F}_{p} = {ρ}_{c} / {ρ}_{f} \qquad [ Relational Equation 1 ]$$

In Relational Equation 1,
Fₚ is the Purcell factor,
ρ_{c} is the density of modes in the resonance, and
ρ_{f} is the density of modes in free space.

For example, in a structure including a non-radiative element 200R, 200G having no direct light emission, for example, in a structure of the lower electrode (Al, RI=0.75+6.02i; 100 nm), the dipole generating layer (RI=1.8, λmax=470 nm; 20 nm), and the upper electrode (Ag, RI=0.13+2.86i; 30 nm), the Purcell factor (Fₚ) for vertically aligned dipoles may be calculated to be about 7.77, which may indicate that the ratio of vertically aligned dipoles among the dipoles in the structure may be very high, about 77.4%. This may be remarkably high compared to a case of a structure using an electroluminescent element such as an OLED instead of a non-radiative element 200R, 200G, the Purcell factor (Fₚ) for vertically aligned dipoles may be calculated to be about 1, which indicates that the ratio of vertically aligned dipoles among the dipoles in the structure may be about 33.3%.

The auxiliary layer 240, 250 may be positioned between the upper electrode 210R, 210G and the dipole generating layer 230, and between the lower electrode 220R, 220G and the dipole generating layer 230, respectively, and may be, for example, a hole injection layer, a hole transport layer, an electron blocking layer, an electron injection layer, an electron transport layer, a hole blocking layer, or a combination thereof. For example, when the lower electrode 220R, 220G is an anode and the upper electrode 210R, 210G is a cathode, the auxiliary layer 240 may be a hole injection layer, a hole transport layer, an electron blocking layer, or a combination thereof, and the auxiliary layer 250 may be an electron injection layer, an electron transport layer, a hole blocking layer, or a combination thereof. At least one of the auxiliary layers 240, 250 may be omitted.

The energy supply element 200 of the third sub-pixel PX₃ may be a radiative element (blue light emitting element 200B), and, unlike the first and second sub-pixels PX₁, PX₂, the third sub-pixel PX₃ displays the same color as the blue wavelength spectrum transferred from the energy supply element 200. Therefore, without a separate light-emitting layer, blue may be displayed in the third sub-pixel PX₃ by directly receiving radiative energy of the blue wavelength spectrum from the blue light emitting element 200B configured to emit light of a blue wavelength spectrum.

The blue light emitting element 200B may be a diode, including an upper electrode 210B and a lower electrode 220B positioned to face each other; a dipole generating layer 230 positioned between the upper electrode 210B and the lower electrode 220B; and auxiliary layers 240, 250 positioned between the upper electrode 210B and the dipole generating layer 230 and between the lower electrode 220B and the dipole generating layer 230.

One of the upper electrode 210B and the lower electrode 220B may be an anode, and the other may be a cathode. The lower electrode 220B may be a pixel electrode independently separated for each third sub-pixel PX₃, and the upper electrode 210B may be a common electrode to which a common voltage is applied. However, in contrast, the lower electrode 220B may be a common electrode and the upper electrode 210B may be a pixel electrode that is independently separated for each third sub-pixel PX₃.

The lower electrode 220B may be an opaque electrode, as described above.

The upper electrode 210B may be a light-transmitting electrode through which light may pass. The light-transmitting electrode may be a transparent electrode or a semi-transparent electrode, and, for example, may be made of a conductive oxide such as ITO, IZO, ZnO, SnO, AlTO, or FTO, or a thin metal film of a single layer or a plurality of layers including a thin thickness (for example, less than about 10 nm) of Ag, Cu, Al, Mg, Mg—Ag, magnesium-aluminum (Mg—Al), or combinations thereof. The third sub-pixel PX₃ may display blue by allowing light of the blue wavelength spectrum supplied from the dipole generating layer 230 to pass through the upper electrode 210B.

For example, the upper electrode 210B of the third sub-pixel PX₃ may be independent from the upper electrode 210R of the first sub-pixel PX₁ and the upper electrode 210G of the second sub-pixel PX₂, respectively. For example, the upper electrode 210B of the third sub-pixel PX₃ may have a material that is the same as or different from the material included in the upper electrode 210R, 210G of the first and second sub-pixels PX₁, PX₂, and, for example, the thickness of the upper electrode 210B of the third sub-pixel PX₃ may be the same as or different from the thickness of the upper electrode 210R, 210G of the first and second sub-pixels PX₁, PX₂.

For example, the lower electrode 220B of the third sub-pixel PX₃ may be independent from the lower electrode 220R of the first sub-pixel PX₁ and the lower electrode 220G of the second sub-pixel PX₂, respectively, and, for example, the lower electrode 220B of the third sub-pixel PX₃ may include a material that is the same as or different from the materials included in the lower electrodes 220R, 220G of the first and second sub-pixels PX₁, PX₂, and, for example, the thickness of the lower electrode 220B of the third sub-pixel PX₃ may be the same as or different from the thicknesses of the lower electrodes 210R, 210G of the first and second sub-pixels PX₁, PX₂.

The dipole generating layer 230 is positioned between the upper electrode 210B and the lower electrode 220B, and may generate dipoles by an electrical stimulus (for example, electrical energy) applied to the upper electrode 210B and the lower electrode 220B. The dipole generating layer 230 may be a common layer formed at the whole surface including the first, second, and third sub-pixels PX₁, PX₂, PX₃, and, as described above, may include an electroluminescent material configured to emit energy corresponding to a blue wavelength spectrum. However, the present disclosure is not limited thereto, and the dipole generating layers 230 of the first, second, and third sub-pixels PX₁, PX₂, PX₃ may each be independent, and at least one of the dipole generating layers 230 of the first, second, and third sub-pixels PX₁, PX₂, PX₃ may be separated.

The auxiliary layer 240, 250 may be positioned between the upper electrode 210B and the dipole generating layer 230, and between the lower electrode 220B and the dipole generating layer 230, respectively, and may be a common layer formed on the entire surface including the first, second, and third sub-pixels PX₁, PX₂, PX₃. However, the present disclosure is not limited thereto, and the auxiliary layers 240, 250 of the first, second, and third sub-pixels PX₁, PX₂, PX₃ may each be independent, and at least one of the auxiliary layers 240, 250 of the first, second, and third sub-pixels PX₁, PX₂, PX₃ may be separated.

For example, at least one of the auxiliary layers 240 of the first, second, and third sub-pixels PX₁, PX₂, PX₃ may include a different material from that of the remaining auxiliary layers 240. For example, at least one of the auxiliary layers 250 of the first, second, and third sub-pixels PX₁, PX₂, PX₃ may include a different material from that of the remaining auxiliary layers 250. For example, at least one of the auxiliary layers 240 of the first, second, and third sub-pixels PX₁, PX₂, PX₃ may have a different thickness from the remaining auxiliary layers 240. For example, at least one of the auxiliary layers 250 of the first, second, and third sub-pixels PX₁, PX₂, PX₃ may have a different thickness from the remaining auxiliary layers 250.

The auxiliary layer 240, 250 may be a charge auxiliary layer to facilitate and/or control charges (for example, holes or electrons) injection and/or charges transport. The charge auxiliary layer may be a hole transport layer, a hole injection layer, an electron blocking layer, an electron transport layer, an electron injection layer, a hole blocking layer, or a combination thereof, but is not limited thereto. The auxiliary layer 240, 250 may include organic material, inorganic material, organic-inorganic material, or a combination thereof, and, for example, may be a metal oxide such as niobium oxide, molybdenum oxide, titanium oxide, or tin oxide; a metal phthalocyanine compound such as copper phthalocyanine; an arylamine-based derivative such as triphenylamine; a carbazole-based derivative such as N-phenylcarbazole or polyvinylcarbazole; and a fluorene-based derivative, but is not limited thereto.

The blue light emitting element 200B, unlike the above-described non-radiative elements 200R, 200G, may be configured to emit to the outside through the upper electrode 210B in the form of radiative energy (photons), and thus may display blue.

A light-emitting layer 500 or a transparent passivation layer 270 is formed on the energy supply element 200 including the non-radiative element 200R, 200G and the blue light emitting element 200B.

The light-emitting layer 500 includes a red light-emitting layer 500R facing the non-radiative element 200R and a green light-emitting layer 500G facing the non-radiative element 200G. The light-emitting layer 500 may include a light-emitting material configured to emit light of a predetermined wavelength spectrum by receiving energy, and, for example, may be quantum dots, perovskite, phosphor, organic light-emitting material, or a combination thereof.

The quantum dots may refer to semiconductor nanocrystals, and may receive energy corresponding to a predetermined wavelength spectrum and emit light of a longer wavelength spectrum. The quantum dots may be configured to emit light in all directions due to isotropic radiative characteristics, so that they may exhibit improved light viewing angles.

The quantum dots may have various shapes including, for example, spherical, pyramidal, multi-arm, cubic, quantum rod, and quantum plate. Herein, the quantum rod may refer to a quantum dot having an aspect ratio of greater than about 1, for example, greater than or equal to about 2, greater than or equal to about 3, or greater than or equal to about 5.

For example, the aspect ratio of the quantum rod may be less than or equal to about 50, less than or equal to about 30, or less than or equal to about 20. The quantum dots may have an average particle diameter (a size of the largest portion for a non-spherical shape) of for example about 1 nm to about 100 nm, about 1 nm to 80 nm, about 1 nm to 50 nm, or about 1 nm to 20 nm.

An energy bandgap of the quantum dots may be adjusted according to the particle size and a composition of the quantum dots, and thus, the light-emitting wavelength of the quantum dots may be controlled. For example, as the particle size of the quantum dots increases, the quantum dots may have a narrower energy bandgap and thus emit light in a relatively long wavelength spectrum. Whereas as the particle size of the quantum dots decreases, the quantum dots may have a wider energy bandgap, and thus, emit light in a relatively short wavelength spectrum. For example, the diameter of the quantum dots may be about 1 nm to 10 nm.

For example, the quantum dots may be configured to emit light of a predetermined wavelength spectrum among the visible light wavelength spectrum depending on their size and/or composition. For example, the quantum dots included in the red light-emitting layer 500R may be configured to selectively emit light of the red light emission spectrum, and may have a peak emission wavelength at, for example, about 610 nm to about 680 nm. For example, the quantum dots included in the green light-emitting layer 500G may be configured to selectively emit light of the green light emission spectrum, and may have a peak emission wavelength at about 520 nm to about 580 nm.

The quantum dots may have a relatively narrow full width at half maximum (FWHM). Herein, the FWHM is a width of a wavelength corresponding to a half of a peak emission point and as the FWHM is narrower, light in a narrower wavelength region may be emitted and high color purity may be obtained. The quantum dots may have, for example, a FWHM of less than or equal to about 50 nm, less than or equal to about 45 nm, less than or equal to about 40 nm, less than or equal to about 35 nm, less than or equal to about 30 nm, or less than or equal to about 28 nm, and within the above range, about 3 nm to about 50 nm, about 3 nm to about 45 nm, about 3 nm to about 40 nm, about 3 nm to about 35 nm, about 3 nm to about 30 nm, or about 3 nm to about 28 nm. Thus, the quantum dots with a relatively narrow FWHM may exhibit excellent color purity and color reproducibility.

For example, the quantum dots may include a Group II-VI semiconductor compound, a Group III-V semiconductor compound, a Group IV-VI semiconductor compound, a Group IV semiconductor element or semiconductor compound, a Group I-III-VI semiconductor compound, a Group I-II-IV-VI semiconductor compound, a Group II-III-V semiconductor compound, or a combination thereof.

The Group II-VI semiconductor compound may include for example a binary element compound of CdS, CdSe, CdTe, ZnS, ZnSe, ZnTe, ZnO, HgS, HgSe, HgTe, MgSe, MgS, or a combination thereof; a ternary element compound of CdSeS, CdSeTe, CdSTe, ZnSeS, ZnSeTe, ZnSTe, HgSeS, HgSeTe, HgSTe, HgZnS, HgZnSe, HgZnTe, MgZnSe, MgZnS, CdZnS, CdZnSe, CdZnTe, CdHgS, CdHgSe, CdHgTe, or a combination thereof; and a quaternary element compound of CdZnSeS, CdZnSeTe, CdZnSTe, CdHgSeS, CdHgSeTe, CdHgSTe, HgZnTeS, HgZnSeS, HgZnSeTe, HgZnSTe, or a combination thereof, but is not limited thereto.

The Group III-V semiconductor compound may include for example a binary element compound of GaN, GaP, GaAs, GaSb, AlN, AlP, AlAs, AlSb, InN, InP, InAs, InSb, or a combination thereof; a ternary element compound of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, or a combination thereof; and a quaternary element compound of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof, but is not limited thereto.

The Group III-V semiconductor compound may further include Group II element. The Group III-V semiconductor compound further including the Group II element may include, for example, InZnP, InGaZnP, InAlZnP, or combinations thereof, but is not limited thereto.

The Group III-VI semiconductor compound may include for example a binary semiconductor compound of GaS, GaSe, Ga₂Se₃, GaTe, InS, InSe, In₂Se₃, InTe, and a combination thereof; a ternary semiconductor compound of InGaS₃, InGaSe₃, and a combination thereof; or combinations thereof, but is not limited thereto.

The Group IV-VI semiconductor compound may include for example a binary semiconductor compound of SnS, SnSe, SnTe, PbS, PbSe, PbTe, and a combination thereof; a ternary semiconductor compound of SnSeS, SnSeTe, SnSTe, PbSeS, PbSeTe, PbSTe, SnPbS, SnPbSe, SnPbTe, and a combination thereof; and a quaternary semiconductor compound of SnPbSSe, SnPbSeTe, SnPbSTe, and a combination thereof; or a combination thereof, but is not limited thereto.

The Group IV element or semiconductor compound may include for example a singular element semiconductor compound of Si, Ge, or a combination thereof; and a binary element semiconductor compound of SiC, SiGe, or a combination thereof, but is not limited thereto.

The Group I-III-VI semiconductor compound may include for example AgInS, AgInS₂, CuInS, CuInS₂, CuInSe₂, CuInGaSe, CuInGaS, CuGaO₂, AgGaO₂, AgAlO₂, and a combination thereof, but is not limited thereto.

The Group I-II-IV-VI semiconductor compound may include for example CuZnSnSe, CuZnSnS, or a combination thereof, but is not limited thereto.

The Group II-III-V semiconductor compound may include for example, InZnP, but is not limited thereto.

The perovskites may include zero-dimensional perovskites such as nanocrystal particles; one-dimensional perovskites in the form of nanowires or nanorods; two-dimensional perovskites such as nanoplatelets; three-dimensional perovskites having a polycrystalline structure in which cations and anions are combined; or a combination thereof.

For example, the perovskites may be an inorganic or organic-inorganic light-absorbing material with a predetermined crystal structure, and, for example, may be Pb-free perovskites not including lead (Pb). The Pb-free perovskite is environmentally friendly as it does not have the harmfulness of lead Pb, and may be effectively applied to semiconductor processes.

For example, the perovskites may be metal halide perovskites including a metal cation and a halide anion. For example, the Pb-free perovskite may be an organic-inorganic metal halide perovskite including an organic cation, a metal cation, and a halide anion. For example, the Pb-free perovskites may be organic-inorganic tin halide perovskites including tin ion Sn²⁺ as the metal cation.

As described above, when using the non-radiative energy of SPP mode transferred from the non-radiative element 200R, 200G having no direct emission (outcoupling), a thick thickness of the light-emitting layer 500 for sufficient absorption is not required, and thus, the thickness of the light-emitting layer 500 may be relatively thin. For example, the thickness of the light-emitting layer 500 may be less than about 1 μm, and within the above range, it may be about greater than or equal to about 2 nm and less than about 1 μm, about 2 nm to about 900 nm, about 2 nm to about 800 nm, about 2 nm to about 600 nm, about 2 nm to about 500 nm, about 2 nm to about 300 nm, about 2 nm to about 200 nm, about 2 nm to about 100 nm, about 2 nm to about 95 nm, about 2 nm to about 90 nm, about 2 nm to about 80 nm, about 2 nm to about 70 nm, about 2 nm to about 60 nm, or about 2 nm to about 50 nm.

As such, the display panel 1000 includes the light-emitting layer 500 with a relatively thin thickness, instead of a conventional light-emitting layer with a thickness of several micrometers to several hundred micrometers, so that the dipoles may be effectively confined or trapped in the in-plane direction of the light-emitting layer 500, increasing the emission of photons to the front side, and preventing the diffusion of photons in the light emitting layer 500 or into the light-emitting layer 500 of adjacent sub-pixels, thereby effectively preventing optical crosstalk. Therefore, it may be not necessary to form a partition or a bank between the light-emitting layers 500 of adjacent sub-pixels for preventing optical crosstalk, and thus the process and structure of the display panel 1000 may be simplified.

The third sub-pixel PX₃ does not include a separate light-emitting layer as described above, and may optionally include a transparent passivation layer 270 to match the step difference with the other sub-pixels PX₁, PX₂. The transparent passivation layer 270 may include a light-transmitting resin, and for example, may include an acrylic resin, urethane resin, silicon resin, epoxy resin, cardo-based resin, imide resin, a derivative thereof, or a combination thereof, but is not limited thereto.

An optical spacer 260 is formed between the light-emitting layer 500 and the energy supply element 200. The optical spacer 260 may be positioned between the light-emitting layer 500 and the energy supply element 200 to effectively adjust the interval between the light-emitting layer 500 and the non-radiative element 200R, 200G, specifically, the interval between the light-emitting layer 500 and the upper electrode 210R, 210B. The thickness of the optical spacer 260 may be, for example, less than about 25 nm, and by having the above thickness, the non-radiative energy of SPP mode from the non-radiative element 200R, 200G may be effectively transferred to the light-emitting layer 500. The thickness of the optical spacer 260 may be about 2 nm to about 23 nm, about 2 nm to about 20 nm, about 5 nm to about 20 nm, or about 5 nm to about 15 nm within the above range.

For example, the transfer efficiency of the non-radiative energy of SPP mode from the non-radiative element 200R, 200G to the light-emitting layer 500 may be confirmed from the ratio of the emission spectrum (red or green wavelength spectrum) of the light-emitting layer 500 to the emission spectrum (blue wavelength spectrum) of the non-radiative element 200R, 200G in the emission spectrum of the color displayed in the first and second sub-pixels PX₁, PX₂ of the display panel 1000 according to the present embodiment, and for example, when the optical spacer 260 has the above thickness, the ratio of the area of the emission spectrum (red or green wavelength spectrum) of the light-emitting layer 500R, 500G to the area of the emission spectrum (blue wavelength spectrum) of the non-radiative element 200R, 200G may be greater than or equal to about 1.0, and within the above range, greater than or equal to about 1.1, greater than or equal to about 1.2, greater than or equal to about 1.3, greater than or equal to about 1.4, greater than or equal to about 1.5, greater than or equal to about 2.0, greater than or equal to about 2.5, or greater than or equal to about 3.0.

The optical spacer 260 may be a common layer formed on the entire surface including the first, second, and third sub-pixels PX₁, PX₂, PX₃, and for example, may include an organic material, an inorganic material, an organic-inorganic material, or a combination thereof. The optical spacer 260 may include a metal oxide such as niobium oxide, molybdenum oxide, titanium oxide, or tin oxide; a metal phthalocyanine compound such as copper phthalocyanine; an arylamine-based derivative such as triphenylamine; a triazine-based derivative such as [(diphenylphosphinyl)phenyl]-1,3,5-triazine; a carbazole-based derivative such as N-phenylcarbazole or polyvinylcarbazole; a fluorene-based derivative; acrylic resin, urethane resin, silicon resin, epoxy resin, cardo-based resin, imide resin, derivatives thereof, or combinations thereof, but is not limited thereto.

As described above, in the display panel 1000 according to the present embodiment, energy corresponding to the blue wavelength spectrum supplied from the energy supply element 200 may be transferred to the light-emitting layers 500R, 500G in the form of non-radiative energy in the first and second sub-pixels PX₁, PX₂, and the radiative energy (photons) may be blocked from escaping to the outside by a pair of opaque electrodes (the upper electrodes and the lower electrodes), thereby providing a filtering effect that blocks the light of the blue wavelength spectrum by itself.

Due to the filtering effect, in a display panel in which light emitted from a typical electroluminescent device (for example, an OLED) is wavelength-converted and photoluminesced by the light-emitting layer, not only may it be possible to effectively prevent unavoidable mixing of light (for example, red light or green light) that is wavelength-converted and photoluminesced by the light-emitting layer and light emitted from the electroluminescent device (for example, blue light), but also, there may be no need to include a separate optical filter (for example, color filters) for preventing such unavoidable color mixing. Accordingly, the first sub-pixel PX₁ may display red and the second sub-pixel PX₂ may display green without a separate optical filter (for example, color filters) for filtering light of the blue wavelength spectrum entering the light-emitting layer 500R, 500G in the first and second sub-pixels PX₁, PX₂. In addition, the third sub-pixel PX₃ may display blue from radiative energy corresponding to the blue wavelength spectrum supplied by the energy supply element 200 without a separate color filter.

In FIG. 2, a display panel 1000 with a top emission structure is illustrated, in which a substrate 110, an energy supply element 200, and a light-emitting layer 500 are sequentially stacked and light is emitted toward the side opposite to the substrate 110. However, the present disclosure is not limited thereto, and the display panel 1000 may have a bottom emission structure in which the substrate 110, the light-emitting layer 500, and the energy supply element 200 are sequentially stacked and light is emitted toward the substrate 110.

The above-described display panel 1000 may be applied to various electronic devices including a display device, and for example, may be applied to a display device such as a TV, monitor, computer, tablet PC, or mobile phone, or to a lighting device such as a light source.

Hereinafter, the embodiments are illustrated in more detail with reference to examples. However, these examples are exemplary, and the present scope is not limited thereto.

### Preparation of Perovskite Nanocrystal Solution

### Preparation Example

Oleic acid and oleylamine serving as ligands are added to a 1-octadecene solvent, and PbBr₂ is further dissolved therein, followed by heating to 165° C. to prepare a reaction precursor solution. Separately, a cesium-oleate (Cs-oleate) solution prepared by dissolving CsCO₃ in a 1-octadecene solvent is rapidly injected into the reaction precursor solution and reacted for several seconds, after which rapid cooling is performed to suppress growth. Thereafter, washing and size separation through a precipitation-redispersion process are performed to prepare a CsPbBr₃ perovskite nanocrystal solution including uniform-sized CsPbBr₃ perovskite nanocrystals.

### Manufacturing of the Device I

### Example 1

The CsPbBr₃ perovskite nanocrystal solution obtained in Preparation Example is spin-coated on a glass substrate at 2000 rpm for 60 seconds and annealed at 80° C. for 5 minutes to form a 30 nm-thick perovskite light-emitting layer (peak emission wavelength: 520 nm) including CsPbBr₃ perovskite nanocrystals. This process is repeated four times to form a 100 nm-thick perovskite light-emitting layer. Subsequently, Compound B is thermally vacuum-deposited on the perovskite light-emitting layer to form a 10 nm-thick optical spacer. Subsequently, Al is thermally vacuum-deposited on the optical spacer to form a 15 nm-thick lower opaque electrode (reflectance: 77.7% and light transmittance: 6.3% at about 475 nm wavelength), and then Compound A (Ossila Ltd.) is deposited thereon to form a 20 nm-thick lower auxiliary layer. Subsequently, Compound A, Compound B (Ossila Ltd.), and Compound C (Ossila Ltd.) are co-deposited at a molar ratio of 0.45:0.45:0.1 on the lower auxiliary layer to form a 30 nm-thick electroluminescent layer (dipole generating layer, EL spectrum: 470-500 nm (skyblue), peak emission wavelength: 475 nm). Subsequently, Compound B is deposited on the electroluminescent layer to form a 20 nm-thick upper auxiliary layer, and then Al is deposited thereon to form a 100 nm-thick upper opaque electrode, manufacturing a device.

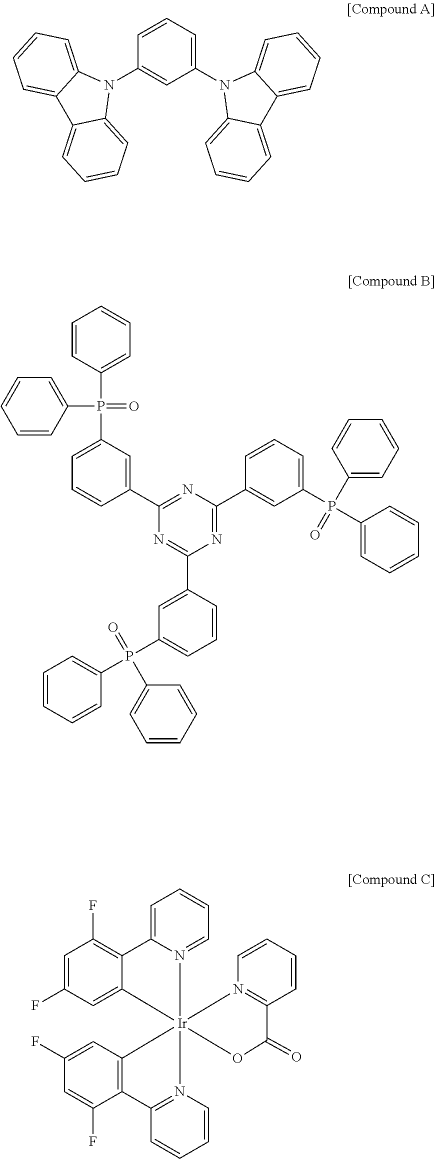

### Reference Example 1

ITO is deposited on a glass substrate to form a 150 nm-thick transparent electrode (light transmittance at a wavelength of about 475 nm: 80% or more). Subsequently, Compound A is deposited on the light transmitting electrode to form a 20 nm-thick lower auxiliary layer, and then Compounds A, B, and C are co-deposited thereon at a molar ratio of 0.45:0.45:0.1 to form a 30 nm-thick electroluminescent layer (EL spectrum: 470-500 nm (skyblue), peak emission wavelength: 475 nm). Then, Compound B is deposited on the electroluminescent layer to form a 20 nm-thick upper auxiliary layer, and Al is deposited thereon to form a 100 nm-thick opaque electrode, manufacturing a non-radiative device.

### Reference Example 2

The CsPbBr₃ perovskite nanocrystal solution obtained in Preparation Example is spin-coated on a glass substrate at 2000 rpm for 60 seconds and annealed at 80° C. for 5 minutes to form a 30 nm-thick perovskite light-emitting layer (peak emission wavelength: 520 nm) including CsPbBr₃ perovskite nanocrystals, manufacturing a photoluminescent device.

### Evaluation I

The emission characteristics of the devices according to Example 1 and Reference Examples 1 and 2 are evaluated.

The emission characteristics of the devices according to Example 1 and Reference Example 1 are evaluated from the peak emission wavelength and the full width at half maximum (FWHM) in the emission spectrum of the devices according to Example 1 and Reference Example 1. Herein, the FWHM is a width of a wavelength corresponding to a half of a peak absorption point in the emission spectrum.

The emission characteristics of the device according to Reference Example 2 is evaluated based on the peak emission wavelength and the FWHM from the photoluminescent spectrum obtained by irradiating the device according to Reference Example 2 with a semiconductor-based solid-state continuous wave laser (λ=405 nm).

The result is shown in Table 1.

TABLE 1

| | Peak Emission Wavelength | | |
|---|---|---|---|
| | (nm) | FWHM (nm) | Color |
| Reference | 475 | 61.1 | Blue |
| Example 1 | | | |
| Reference | 520 | 21 | Green |
| Example 2 | | | |
| Example 1 | 520 | 33.4 | Green |

Referring to Table 1, it may be confirmed that the device according to Example exhibits emission characteristics similar to those of the device according to Reference Example 2, that is, the perovskite light-emitting layer.

From this, it may be confirmed that the perovskite light-emitting layer with relatively thin thickness in the device according to Example may effectively absorb the non-radiative energy transferred from the electroluminescent layer (dipole generating layer) positioned between a pair of opaque electrodes and may effectively emit light of the green wavelength spectrum.

### Manufacturing of the Device II

### Example 2

Al is deposited on a glass substrate to form an 80 nm-thick lower opaque electrode. Subsequently, Compound B is thermally vacuum-deposited on the lower opaque electrode to form a 20 nm-thick lower auxiliary layer and Compound A, Compound B, and Compound C are co-deposited at a molar ratio of 0.45:0.45:0.1 on the lower auxiliary layer to form a 30 nm-thick electroluminescent layer (dipole generating layer, EL spectrum: 470-500 nm (skyblue), peak emission wavelength: 470 nm). Subsequently, on the electroluminescent layer, Compounds D (Lumtec) and MoO₃ are sequentially deposited with a thickness of 18 nm and 2 nm, respectively, to form an upper auxiliary layer, and Ag is deposited thereon to form an upper opaque electrode with a thickness of 40 nm. Subsequently, Compound A is thermally vacuum-deposited on the upper opaque electrode to form a 10 nm-thick optical spacer. Subsequently, the CsPbBr₃ perovskite nanocrystal solution obtained in Preparation Example is spin-coated on the optical spacer at 2000 rpm for 60 seconds and annealed at 80° C. for 5 minutes to form a 30 nm-thick perovskite light-emitting layer including CsPbBr₃ perovskite nanocrystals. This process is repeated four times to form a 100 nm-thick perovskite light-emitting layer (peak emission wavelength: 510 nm), manufacturing a device.

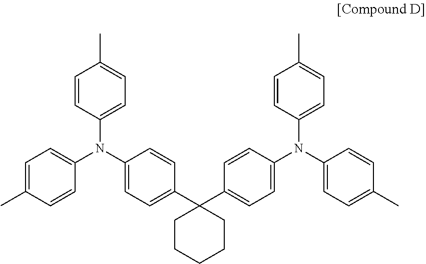

### Example 3

A device is manufactured in the same manner as in Example 2, except that a 20 nm-thick optical spacer is formed instead of a 10 nm-thick optical spacer.

### Reference Example 3

Al is deposited on a glass substrate to form an 80 nm-thick lower opaque electrode. Subsequently, Compound B is thermally vacuum-deposited on the lower opaque electrode to form a 20 nm-thick lower auxiliary layer and Compound A, Compound B, and Compound C are co-deposited at a molar ratio of 0.45:0.45:0.1 thereon to form a 30 nm-thick electroluminescent layer (dipole generating layer, EL spectrum: 470-500 nm (skyblue), peak emission wavelength: 470 nm). Subsequently, on the electroluminescent layer, Compounds D (Lumtec) and MoO₃ are sequentially deposited with a thickness of 18 nm and 2 nm, respectively, to form an upper auxiliary layer, and Ag is deposited thereon to form an upper opaque electrode with a thickness of 40 nm, manufacturing a non-radiative device.

### Reference Example 4

The CsPbBr₃ perovskite nanocrystal solution obtained in Preparation Example is spin-coated on a glass substrate at 2000 rpm for 60 seconds and annealed at 80° C. for 5 minutes to form a 30 nm-thick perovskite light-emitting layer including CsPbBr₃ perovskite nanocrystals. This process is repeated four times to form a 100 nm-thick perovskite light-emitting layer (peak emission wavelength: 510 nm), manufacturing a photoluminescent device.

### Reference Example 5

A device is manufactured in the same manner as in Example 2, except that a 20 nm-thick optical spacer is formed instead of a 10 nm-thick optical spacer.

### Reference Example 6

A device is manufactured in the same manner as in Example 2, except that a 20 nm-thick optical spacer is formed instead of a 10 nm-thick optical spacer.

### Evaluation II

The emission characteristics of the devices according to Example 2 and Reference Examples 3 and 4 are evaluated.

The methods for evaluating luminescence characteristics are as described above.

The results are shown in Table 2.

TABLE 2

| | Peak Emission Wavelength | | |
|---|---|---|---|
| | (nm) | FWHM (nm) | Color |
| Reference | 470 | 49 | Blue |
| Example 3 | | | |
| Reference | 510 | 30.2 | Green |
| Example 4 | | | |
| Example 2 | 510 | 34.5 | Green |

Referring to Table 2, it may be confirmed that the device according to Example 2 exhibits emission characteristics similar to those of the device according to Reference Example 4, that is, the perovskite light-emitting layer.

From this, it may be confirmed that the perovskite light-emitting layer with relatively thin thickness in the device according to Example 2 may effectively absorb the non-radiative energy transferred from the electroluminescent layer (dipole generating layer) positioned between a pair of opaque electrodes and may effectively emit light of the green wavelength spectrum.

### Evaluation III

The emission characteristics according to the thickness of the optical spacer are evaluated for the devices according to Examples 2 and 3 and Reference Examples 5 and 6.

The emission characteristics are evaluated by separating the emission spectrum (green) of the perovskite light-emitting layer from the emission spectrum of the non-radiative device (blue) in the emission spectra of the devices according to Examples 2 and 3 and Reference Examples 5 and 6, and then calculating the ratio of the area (AG) of the emission spectrum (green) of the perovskite light-emitting layer to the area (AB) of the emission spectrum (blue) of the non-radiative device.

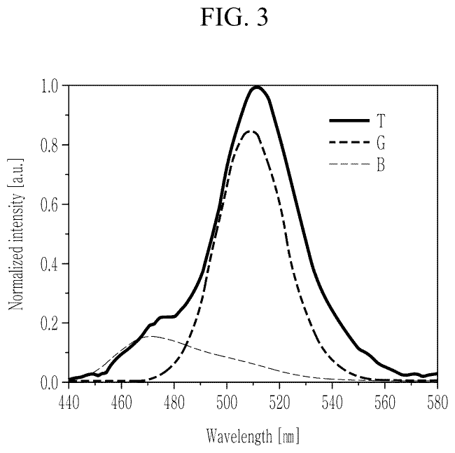

The results are shown in Table 3 and FIGS. 3 to 6.

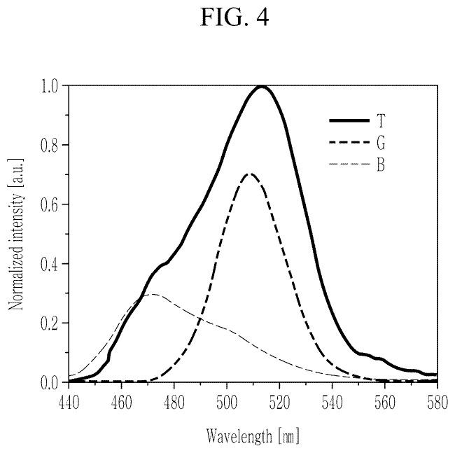

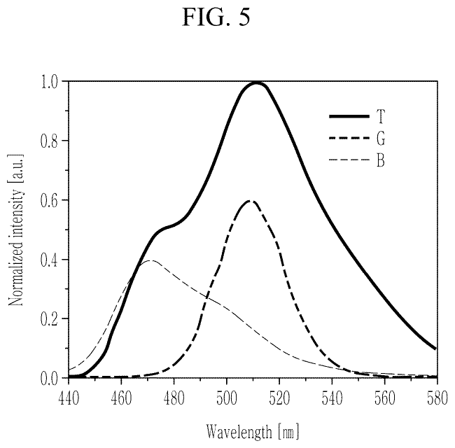

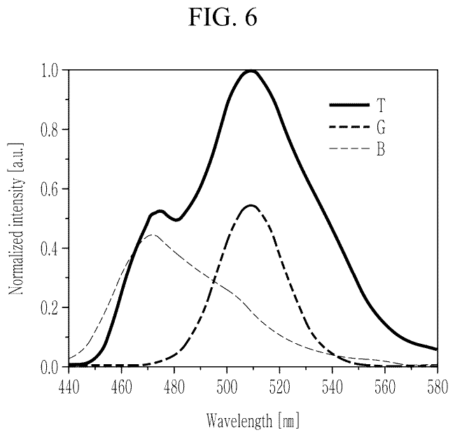

FIG. 3 is a graph showing the emission spectrum (T) of the device according to Example 2, the emission spectrum of the perovskite light-emitting layer (green, G), and the emission spectrum of the non-radiative element (blue, B), FIG. 4 is a graph showing the emission spectrum (T) of the device according to Example 3, the emission spectrum of the perovskite light-emitting layer (green, G), and the emission spectrum of the non-radiative element (blue, B), FIG. 5 is a graph showing the emission spectrum (T) of the device according to Reference Example 5, the emission spectrum of the perovskite light-emitting layer (green, G), and the emission spectrum of the non-radiative element (blue, B), and FIG. 6 is a graph showing the emission spectrum (T) of the device according to Reference Example 6, the emission spectrum of the perovskite light-emitting layer (green, G), and the emission spectrum of the non-radiative element (blue, B).

TABLE 3

| | A_{G}/A_{B} |
|---|---|
| Example 2 | 3.53 |
| Example 3 | 1.45 |
| Reference Example 5 | 0.94 |
| Reference Example 6 | 0.76 |

Referring to Table 3 and FIGS. 3 to 6, it may be confirmed that as the optical spacer becomes thicker in the devices according to Examples 2 and 3 and Reference Examples 5 and 6, the ratio of the emission spectrum (green) of the light-emitting device to the area (AB) of the emission spectrum (blue) of the non-radiative device decreases.

Whereas there may be no change in the emission spectrum according to the thickness of the optical spacer in a general photoluminescent device that emits light by wavelength conversion through direct emission from a general EL device (e.g., an OLED), a change in the emission spectrum according to the thickness of the optical spacer in the devices according to Examples 2 and 3 and Reference Examples 5 and 6 is observed. Therefore, it may be expected that in the devices according to Examples 2 and 3 and Reference Examples 5 and 6, the non-radiative energy supplied from the electroluminescent layer is converted into SPP mode formed at the surface of the upper opaque electrode and transferred to the perovskite light-emitting layer, thereby causing a change in the emission spectrum.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A display panel comprising:
a non-radiative element, and
a light-emitting layer configured to emit light of a first wavelength spectrum from non-radiative energy transferred from the non-radiative element.

2. The display panel of claim 1, wherein the non-radiative element is a non-radiative diode including a first opaque electrode positioned adjacent to the light-emitting layer.

3. The display panel of claim 2, wherein the non-radiative diode further comprises:
a second opaque electrode facing the first opaque electrode, and
a dipole generating layer between the first opaque electrode and the second opaque electrode.

4. The display panel of claim 3, wherein a ratio of the vertically aligned dipoles among dipoles in the dipole generating layer is greater than about 50%.

5. The display panel of claim 3, wherein
the dipole generating layer comprises an electroluminescent material configured to emit light of a second wavelength spectrum that is shorter than the first wavelength spectrum,
the electroluminescent material is configured to convert electrical energy into radiative energy and the non-radiative energy, and
the radiative energy is confined or trapped in the dipole generating layer.

6. The display panel of claim 5, wherein the non-radiative energy is converted into a surface plasmon polariton mode at a surface of the first opaque electrode and transferred to the light-emitting layer.

7. The display panel of claim 5, wherein
the first wavelength spectrum is a green wavelength spectrum or a red wavelength spectrum, and
the second wavelength spectrum is a blue wavelength spectrum.

8. The display panel of claim 5, wherein the external quantum efficiency of the non-radiative diode is less than about 1%.

9. The display panel of claim 5, wherein the first opaque electrode comprises a metal layer having a light-transmittance of less than about 30% for light of the second wavelength spectrum.

10. The display panel of claim 2, wherein a distance between the light-emitting layer and the first opaque electrode is less than about 25 nm.

11. The display panel of claim 1, wherein a thickness of the light-emitting layer is greater than or equal to about 2 nm and less than about 1 μm.

12. The display panel of claim 1, wherein the light-emitting layer comprises quantum dots, perovskites, phosphors, organic light-emitting materials, or a combination thereof.

13. A display panel comprising a first sub-pixel displaying red, a second sub-pixel displaying green, and a third sub-pixel displaying blue,
wherein
the first sub-pixel comprises
a first non-radiative element, and
a red light-emitting layer configured to emit light of a red wavelength spectrum from non-radiative energy transferred from the first non-radiative element, and
the second sub-pixel comprises
a second non-radiative element, and
a green light-emitting layer configured to emit light of a green wavelength spectrum from non-radiative energy transferred from the second non-radiative element.

14. The display panel of claim 13, wherein the first non-radiative element and the second non-radiative element each comprise:
a first opaque electrode positioned adjacent to the red light-emitting layer or the green light-emitting layer,
a second opaque electrode opposing the first opaque electrode, and
a dipole generating layer positioned between the first opaque electrode and the second opaque electrode, and
wherein the dipole generating layer includes an electroluminescent material configured to emit energy corresponding to a blue wavelength spectrum.

15. The display panel of claim 14, wherein
the electroluminescent material is configured to convert electrical energy into radiative energy and the non-radiative energy,
the radiative energy is confined or trapped in the dipole generating layer, and
the non-radiative energy is converted into a surface plasmon polariton mode at a surface of the first opaque electrode and transferred to the red light-emitting layer and the green light-emitting layer, respectively.

16. The display panel of claim 14, wherein a ratio of the vertically aligned dipoles among dipoles in the dipoles generating layer is greater than about 50%.

17. The display panel of claim 14, wherein
the first opaque electrode comprises a metal layer having a light-transmittance of less than about 30% for light in the blue wavelength spectrum, and
a thickness of each of the red light-emitting layer and the green light-emitting layer is greater than or equal to about 2 nm and less than about 1 μm.

18. The display panel of claim 13, wherein the third sub-pixel comprises a radiative element including an electroluminescent material configured to emit light of a blue wavelength spectrum.

19. The display panel of claim 13, wherein the display panel does not comprise a color filter.

20. An electronic device comprising the display panel of claim 1.
